(19) United States
(12) Patent Application Publication
(10) Pub. No.: US 2025/0176408 A1
(43) Pub. Date: May 29, 2025

(54) DISPLAY DEVICE

(71) Applicant: LG Display Co., Ltd., Seoul (KR)

(72) Inventors: Jong Hoon YEO, Paju-si (KR); Mi Jin JEONG, Paju-si (KR); Jeong Beom LEE, Paju-si (KR); Jong Ho KIM, Paju-si (KR)

(73) Assignee: LG Display Co., Ltd., Seoul (KR)

(21) Appl. No.: 18/962,384

(22) Filed: Nov. 27, 2024

(30) Foreign Application Priority Data
Nov. 29, 2023 (KR) 10-2023-0169305

(51) Int. Cl. H10K 59/80; H10K 59/131

(52) U.S. Cl. CPC H10K 59/873; H10K 59/131

(57) ABSTRACT

A display device including a substrate including a display area and a non-display area, an encapsulation layer disposed in the display area and the non-display area, the encapsulation layer including a first encapsulation layer, an organic encapsulation layer, and a second encapsulation layer, a dam disposed around the encapsulation layer in the non-display area, and at least one stopper disposed inside the dam, wherein the first encapsulation layer has an opening in an area corresponding to the at least one stopper.

### CROSS-REFERENCE TO RELATED APPLICATIONS

This application claims the benefit of and the priority to Korean Patent Application No. 10-2023-0169305, filed on Nov. 29, 2023, which is hereby incorporated by reference as if fully set forth herein.

### BACKGROUND

### Technical Field

The present disclosure relates to a display device to form a narrow bezel and to improve reliability.

### Discussion of the Related Art

Display devices for displaying images in TVs, monitors, mobile phones, tablet computers, and laptops are used in various modes and configurations.

Display devices include a display panel having a plurality of light-emitting elements or liquid crystals for displaying an image, and transistors for controlling the operation of each light-emitting element or liquid crystal, to display an image through the light-emitting elements or liquid crystals.

Organic light-emitting display devices including self-luminous elements may be thinner than display devices including a light source and do not require a separate light source, thus realizing display devices that are bendable or have various designs.

With the advent of the information society, displays for visually expressing electrical information signals have developed rapidly. In response to this, research is underway on development of various display devices with excellent performance such as narrow bezel, lower power consumption and reliability.

### SUMMARY

Accordingly, the disclosure is directed to a display device that substantially obviates one or more problems due to the limitations and disadvantages of the related art.

It is one object of the present disclosure to provide a display device that is capable of improving reliability by preventing permeation of moisture or oxygen from outside.

It is another object of the present disclosure to provide a display device that is capable of effectively controlling the flow of the organic encapsulation layer.

It is another object of the present disclosure to provide a display device with a narrow bezel.

It is another object of the present disclosure to provide a display device that is advantageous for recycling by reducing the consumption of materials throughout the process such as gas and etchants to form material layers used in the display device.

Additional advantages, objects, and features of the disclosure will be set forth in part in the description which follows and in part will become apparent to those having ordinary skill in the art upon examination of the following, or may be learned from practice of the disclosure. The objectives and other advantages of the disclosure may be realized and attained by the structure particularly pointed out in the written description and claims hereof as well as the appended drawings.

To achieve these and other advantages and in accordance with objects of the disclosure, as embodied and broadly described herein, a display device includes a substrate including a display area and a non-display area, an encapsulation layer at the display area and the non-display area, the encapsulation layer including a first encapsulation layer, an organic encapsulation layer, and a second encapsulation layer, a dam around the encapsulation layer at the non-display area, and at least one stopper disposed at an inner area than the dam, wherein the first encapsulation layer has an opening in an area corresponding to the at least one stopper.

The at least one stopper may comprise a plurality of stoppers spaced apart from each other. A surface energy or a surface tension of the plurality of stoppers may be higher than a surface energy or surface tension of a film disposed at a space between the plurality of stoppers.

The organic encapsulation layer may contact the at least one stopper through the opening of the first encapsulation layer.

The at least one stopper may comprise a plurality of stoppers including an inorganic material in an upper part thereof. A first organic film may be disposed between the stoppers, and the organic encapsulation layer may alternately contact a top surface of the inorganic material of the stopper and a top surface of the first organic film through the opening of the first encapsulation layer.

The first encapsulation layer may not overlap the plurality of stoppers and the first organic film exposed between the plurality of stoppers through the opening.

The at least one stopper may comprise a plurality of stoppers. A width of the opening of the first encapsulation layer may be greater than a total width of the stoppers.

The display device may further include a light-emitting element disposed at the display area and including a first electrode, an organic light-emitting layer, and a second electrode, wherein the at least one stopper contains the same material as the first electrode.

The stopper according to another embodiment may include a first stop pattern layer and a second stop pattern layer disposed below the first stop pattern layer, wherein the first stop pattern layer contains the same material as the connection electrode and the second stop pattern layer contains the same material as the second organic film.

A plurality of stoppers including the stopper may be disposed, a trench may be disposed between the stoppers, and the organic encapsulation layer may fill the inside of the trench.

Each of the stoppers may have a first point and a second point disposed in opposite directions to each other, the first point may protrude toward the display area, and the second point may protrude toward the dam.

A plurality of first points including the first point and a plurality of second points including the second point may be disposed, the first points and the second points may be alternately connected to each other, and the trench corresponding to the second points may have a pattern protruding toward the dam.

It is to be understood that both the foregoing general description and the following detailed description of the disclosure are by way of example and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure.

In the drawings:

FIG. 1 is a plan view illustrating a display device according to one embodiment;

FIG. 2 is a circuit diagram illustrating a sub-pixel according to one embodiment;

FIG. 3 is a cross-sectional view taken along line I-I′ of FIG. 1;

FIG. 4 is an enlarged partial plan view illustrating portion A of FIG. 1;

FIG. 5 illustrates a stopper according to one embodiment;

FIG. 6 illustrates a stopper according to another embodiment; and

FIG. 7 is an enlarged partial plan view illustrating portion A of FIG. 1 according to another embodiment.

### DETAILED DESCRIPTION OF THE INVENTION

Hereinafter, embodiments will be described with reference to the drawings.

Like reference numbers refer to like components throughout the description of the figures. The thickness, ratio, size, and the like of components shown in the drawings to illustrate various embodiments of the present disclosure are exaggerated for better illustration. The scale of the components shown in the drawings is different from the actual scale for better illustration and is therefore not limited to the scale shown in the drawings.

It will be understood that, when an element (or a region, layer, film or part) is referred to as being “on”, “connected to” or “bound to” another element, it may be directly on, connected to or bound to the other element, or an intervening element may also be present therebetween.

The expression “and/or” includes all combinations of one or more that the associated configurations may define.

In describing the variety of embodiments of the present disclosure, terms such as “first” and “second” may be used to describe a variety of components, but these terms only aim to distinguish the same or similar components from one another. Accordingly, throughout the disclosure, a “first” component may be referred to as a “second” component within the technical concept of the present disclosure. Similarly, a “second” component may be referred to as a “first” component within the technical concept of the present disclosure. Singular forms are intended to include plural forms as well, unless the context clearly indicates otherwise.

Spatially relative terms, such as “below”, “beneath”, “above”, and “upper”, may be used herein to describe the relationship between elements as shown in the figures. It will be understood that these terms are spatially relative and thus described based on the orientation depicted in the figures. For example, at least one intervening element may be present between the two elements, unless “immediately” or “directly” is used. Spatially relative terms, such as “below”, “beneath”, “above”, and “upper”, may be used herein to easily describe the correlation between one element or component and other elements or components. It will be understood that spatially relative terms are intended to encompass different orientations of a device during the use or operation of the device, in addition to the orientation depicted in the figures. For example, if a device in one of the figures is turned upside down, elements described as “below” or “beneath” other elements would then be positioned “above” the other elements. The exemplary term “below” or “beneath” can, therefore, encompass the meanings of both “below” and “above”.

It will be further understood that the terms “comprises” and/or “has”, when used in this specification, specify the presence of stated features, integers, steps, operations, elements, parts or combinations thereof, but do not preclude the presence or addition of one or more other features, integers, steps, operations, elements, parts, or combinations thereof.

Features of various embodiments of the present disclosure may be partially or completely integrated or combined with each other, and may be variously interoperated with each other and driven technically. The embodiments of the present disclosure may be carried out independently from each other, or may be carried out together in an interrelated manner.

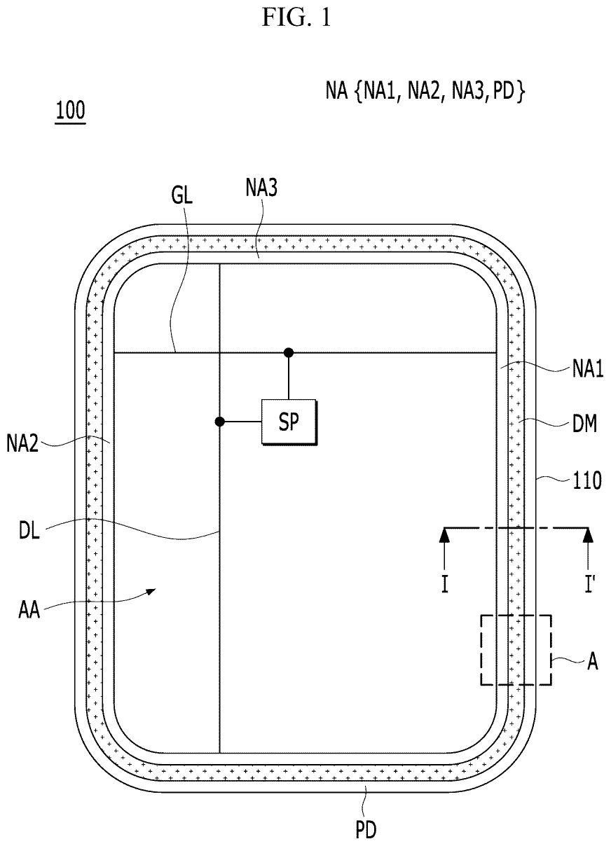

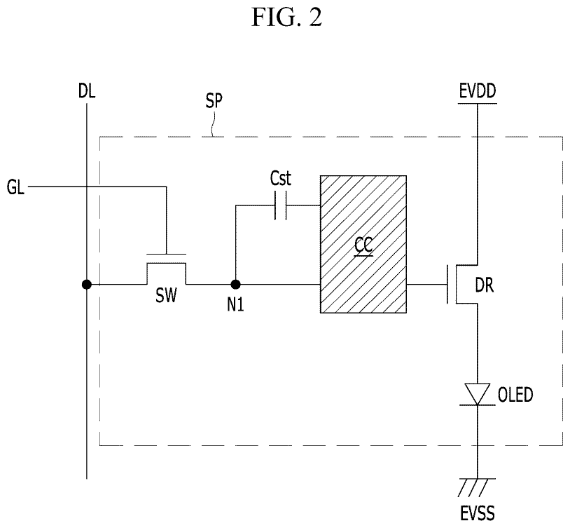

Hereinafter, a display device according to an embodiment of the present disclosure will be described in detail with reference to the attached drawings. FIG. 1 is a plan view illustrating a display device according to one embodiment, and FIG. 2 is a circuit diagram illustrating a sub-pixel according to one embodiment.

With reference to FIGS. 1 and 2, the display device 100 according to an example of the present disclosure includes a display panel 110 including a display area AA and a non-display area NA.

The display area AA is an area that displays an image. A plurality of sub-pixels SP are disposed in the display area AA of the display panel 110, and an image may be displayed using the plurality of sub-pixels SP. The area where the plurality of sub-pixels SP are arranged may be the display area AA, and the area other than the display area AA may be the non-display area NA.

The non-display area NA may be disposed in an edge area surrounding the display area AA that displays the image. The non-display area NA may be divided into a first non-display area NA1, a second non-display area NA2, a third non-display area NA3, and a pad area PD along the perimeter of the display area AA.

The pad area PD is an area where structures for receiving external signals are disposed, and for example, a driver integrated circuit (D-IC) such as a data driver IC may be disposed.

The non-display area NA surrounding the display area AA excluding the pad area PD of the non-display area NA is referred to as first to third non-display areas NA1 to NA3, but this is provided for better illustration and the location of each area is not limited thereto.

At least one driver for driving a plurality of sub-pixels SP may be disposed in at least one of the first non-display area NA1 and the second non-display area NA1. The driver may be a gate-in-panel (GIP).

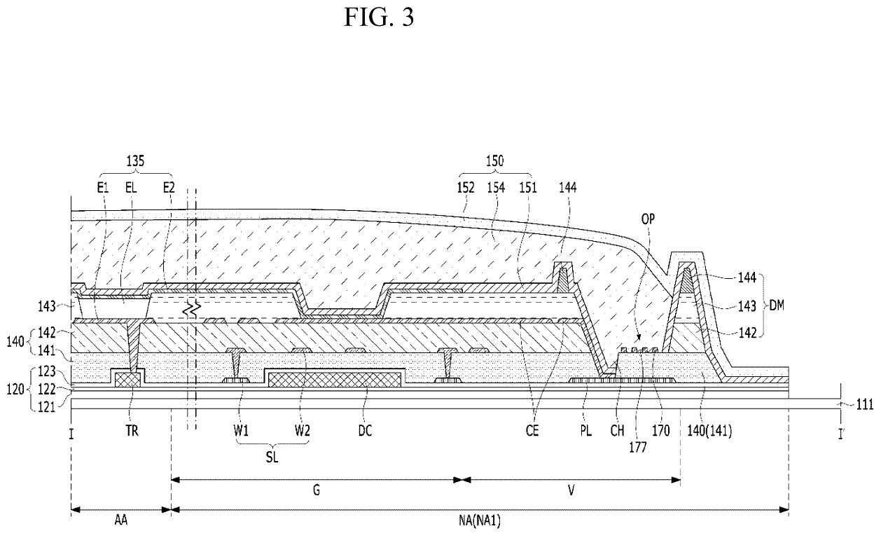

A dam DM may be disposed in the non-display area NA surrounding the display area AA. The dam DM may be disposed in the first to third non-display areas NA1 to NA3 and the pad area PD. The dam DM may be disposed at the outside of the non-display area NA to control the flow of an organic encapsulation layer 154 (see FIG. 3) to prevent moisture from permeating into various elements and lines of the display panel 110. In other words, the dam DM may be disposed at an outer edge region of the non-display area NA.

Various additional elements may be further disposed in the non-display area NA to drive sub-pixels in the display area AA.

With reference to FIG. 2, among the pixels, at least one sub-pixel SP includes a switching transistor SW, a driving transistor DR, a capacitor Cst, a compensation circuit CC, and an organic light-emitting diode (OLED, 135, see FIG. 3).

A first electrode (e.g., drain electrode) of the switching transistor SW is electrically connected to the data line DL, and a second electrode (e.g., source electrode) of the switching transistor SW is electrically connected to a first node N1. A gate electrode of the switching transistor SW is electrically connected to the gate line GL. The switching transistor SW transmits the data signal supplied through the data line DL to the first node N1 in response to the scan signal supplied through the gate line GL.

The capacitor Cst is electrically connected to the first node N1 and charges the voltage applied to the first node N1.

A first electrode (e.g., drain electrode) of the driving transistor DR receives a high potential driving voltage (EVDD), and a second electrode (e.g., source electrode) of the driving transistor DR is electrically connected to a first electrode (e.g., an anode). The driving transistor DR can control the amount of driving current flowing through the organic light-emitting diode (OLED) in response to the voltage applied to the gate electrode of the driving transistor DR.

A semiconductor layer of the switching transistor SW and/or the driving transistor DR may contain silicon such as amorphous silicon (a-Si), polycrystalline silicon (poly-Si), or low-temperature polycrystalline silicon (poly-Si), or may contain an oxide such as IGZO (indium-gallium-zinc-oxide), but is not limited thereto.

The organic light-emitting diode (OLED) outputs light corresponding to the driving current. The organic light-emitting diode (OLED) may output light with any one of red, green, blue, and white.

The organic light-emitting diode (OLED) may include an anode, a light-emitting layer disposed on the anode, and a cathode supplying a common voltage. The light-emitting layer may be implemented to emit light of the same color for each pixel, such as white light, or may be implemented to emit different colors for each sub-pixel SP, such as red, green, or blue light.

The organic light-emitting diode (OLED) may be a front-emitting diode or a back-emitting diode.

The compensation circuit CC may be provided in the sub-pixel SP to compensate for a threshold voltage of the driving transistor DR. The compensation circuit CC may include one or more transistors. The compensation circuit CC may include at least one transistor and capacitor, and may be configured in various configurations depending on the compensation method. The sub-pixel SP including the compensation circuit CC may have various structures such as 3T1C, 4T2C, 5T2C, 6T1C, 6T2C, 7T1C, and 7T2C.

With reference to FIG. 3, the display panel 110 includes a substrate 111. The area on the substrate 111 may be divided into a display area AA and a non-display area NA.

As shown in FIG. 1 and FIG. 3, the display area AA is an area where an image is displayed, and transistors TR and light-emitting diodes 135 for driving a plurality of sub-pixels SP are disposed. In the non-display area NA, various signal lines SL, power lines PL, and driving circuits DCs for driving the transistor TR and the light-emitting diode 135 of the display area AA may be disposed.

The non-display area NA may include a driving circuit area G and a power line area V. Although the disclosure will be described based on the first non-display area NA1 as an example, the disposition of the driving circuit area G and the power line area V is not limited to the example of the first non-display area NA1. The second non-display area NA2 and the third non-display area NA3 may also include a driving circuit area G and a power line area V. In the second non-display area NA2, the driving circuit area G and the power line area V may be arranged symmetrically with the first non-display area NA1 with the display area AA interposed therebetween.

The substrate 111 serves to support and protect the components of the display device 100 disposed on the substrate 111.

The substrate 111 may be formed of a flexible plastic material and may be thus flexible. The substrate 111 may be formed of polyimide and may contain a flexible and thin glass material.

The substrate 111 may independently include a support substrate such as PET (polyethylene terephthalate) and a polyimide film. The substrate 110 may include an adhesive film such as a pressure sensitive adhesive (PSA) to adhere the PET to the polyimide film.

The substrate 111 may have a structure in which two layers are stacked via an intermediate layer (not shown) interposed therebetween.

A plurality of insulating films 120 are stacked on the display area AA and the non-display area NA of the substrate 111. The insulating film 120 may include a first insulating film 121, a second insulating film 122, and a third insulating film 123.

The first insulating film 121 is disposed in the display area AA and the non-display area NA on the substrate 111. The first insulating film 121 may be called a “buffer film” and may have the same function as the buffer film known in the technical field. The first insulating film 121 is disposed on the substrate 111 to protect structures on the substrate 111 that are vulnerable to moisture permeation from moisture penetrating through the substrate 111 and to planarize the surface of the substrate 111.

The first insulating film 121 may be disposed in the driving circuit area G and the power line area V of the non-display area NA as well. The first insulating film 121 is disposed on the edge of the substrate 111 to prevent moisture from penetrating from the edge of the substrate 111. The first insulating film 121 may be arranged to overlap the dam DM disposed at the outside of the substrate 111.

The first insulating film 121 may be a single inorganic film or may include a plurality of inorganic films alternately stacked. For example, the first insulating film 121 may include at least one inorganic film selected from the group consisting of a silicon oxide (SiOx) film, a silicon nitride (SiNx), and a silicon oxynitride (SiOxNy) film, or may include a multilayer film in which the inorganic films described above are stacked.

The transistor TR may be disposed on the substrate 111 and may be the switching transistor SW or the driving transistor DR described in FIG. 2. The transistor TR may include a gate electrode, a source electrode, a drain electrode, and a semiconductor layer. The transistor TR may be disposed on the first insulating film 121.

The gate electrode serves to turn on or off the transistor TR based on an electrical signal transmitted externally through the gate line GL or data line DL, and a may be a single layer or multiple layers of a conductive metal such as copper (Cu), aluminum (Al), molybdenum (Mo), chromium (Cr), gold (Au), titanium (Ti), nickel (Ni), or neodymium (Nd), or an alloy thereof, but is not limited thereto.

The source electrode and the drain electrode may be a single layer or multiple layers of a conductive metal such as copper (Cu), aluminum (Al), molybdenum (Mo), chromium (Cr), gold (Au), titanium (Ti), nickel (Ni), or neodymium (Nd), or an alloy thereof, but is not limited thereto.

The transistor TR connected to the light-emitting diode 135 is shown as an example among the various transistors TR constituting the display device 100 for better illustration in the drawings, but the same structure is applied to other switching transistors SW and is not limited to transistors that function as driving transistors DR.

The second insulating film 122 is disposed on the first insulating film 121. The second insulating film 122 is disposed in the display area AA to prevent short circuits between the gate electrodes constituting the transistors TR and the semiconductor layers. The second insulating film 122 may be referred to as a “gate insulating film” and may function as a generally known gate insulating film.

The second insulating film 122 extends to the non-display area NA to prevent short circuits between electrodes constituting the driving circuit DC disposed in the non-display area NA or short circuits between the electrode and the semiconductor layer. The second insulating film 122 may be arranged to overlap the dam DM at the outside of the non-display area NA.

The second insulating film 122 may include an inorganic film, for example, a silicon oxide (SiOx) film, a silicon nitride (SiNx) film, or a multi-film thereof.

The third insulating 123 is disposed on the second insulating film 122. The third insulating film 123 may be disposed in the display area AA to insulate electrodes constituting the transistor TR on the substrate 111 from each other. The third insulating film 123 may be referred to as an “interlayer insulating film” and may function as an interlayer insulating film known in the relevant technical field.

The third insulating film 123 extends to the non-display area NA to electrically insulate electrodes disposed above and below the transistors constituting the driving circuit DC disposed in the non-display area NA. The third insulating layer 123 may be arranged to overlap the dam DM at the outside of the non-display area NA.

The third insulating film 123 may include an inorganic material. The inorganic material may include, for example, silicon nitride, silicon oxynitride, or silicon oxide. Alternatively, the third insulating film 123 may include a multi-film thereof.

A driving circuit DC, at least one signal line SL, and at least one power line PL may be disposed on the substrate 111 in the non-display area NA.

The driving circuit DC may be disposed on the insulating film 120 at the driving circuit area G of the non-display area NA. When the driving circuit DC is disposed in the first non-display area NA1 and the second non-display area NA2, the driving circuit DC may function as a gate driving circuit or a light-emitting driving circuit. When the driving circuit DC is disposed in the third non-display area NA3 or the pad area PD, the driving circuit DC may function as an anti-static circuit or a multiplexer circuit.

The driving circuit DC may include a plurality of transistors, and the transistors of the driving circuit DC of the non-display area NA may have the same structure or be disposed on the same layer as the transistor TR of the display area AA.

Although the driving circuit DC is disposed on the second insulating film 122 in FIG. 3, this is shown as an example for better illustration and the driving circuit DC may be disposed on any one of the first insulating film 121 and the second insulating film 122.

The signal line SL may be disposed on the insulating film 120 on the driving circuit area G of the non-display area NA. The signal line SL may be a data control line, a gate control line, or a gate voltage application signal line. As shown in FIG. 3, when the signal line SL is disposed in the first non-display area NA1, the signal line SL may be a gate control line or a gate voltage application signal line.

The signal line SL may be disposed adjacent to the driving circuit DC in the driving circuit area G on the same layer as the driving circuit DC and spaced apart from the driving circuit DC, or may be disposed to overlap the driving circuit DC.

The signal line SL may include a first signal line W1 and a second signal line W2.

The first signal line W1 is shown as being disposed on the third insulating film 123 in FIG. 3, but this is shown as an example for better illustration and the first signal line W1 may be disposed on any one of the first insulating film 121, the second insulating film 122 and the third insulating film 123 of the insulating film 120.

The first signal line W1 of the driving circuit area G may be formed of the same material as the material constituting the electrode disposed on any one of the first to third insulating films 121 to 123. The first signal line W1 may be formed of the same material as the electrode constituting the driving circuit DC of the non-display area NA.

The second signal line W2 may be disposed on the insulating film 120 in the driving circuit area G and spaced apart from the first signal line W1. In this case, the second signal line W2 may be disposed on a first organic film 141. The first organic film 141 may have a planarized surface of thereof.

A plurality of second signal lines W2 are disposed on the first organic film 141 such that at least one second signal line W2 overlaps and is electrically connected to the first signal line W1. Some second signal lines W2 may not overlap the first signal line W1 and overlap the driving circuit DC adjacent to the first signal line W1.

Some second signal lines W2 are disposed on the driving circuit DC of the non-display area NA to overlap the driving circuit DC to reduce the width of the non-display area NA constituting a bezel. Therefore, the display device 100 according to the present disclosure can provide a narrow bezel.

The second signal line W2 in the driving circuit area G may be formed of the same material as the electrode constituting the transistor TR in the display area AA or the electrode disposed on the first organic film 141 in the display area AA.

The non-display area NA includes a power line area V and the power line area V may be disposed outside the driving circuit area G. A power line PL may be disposed in the power line area V. The power line PL may be disposed between the driving circuit DC and the dam DM.

The power line PL may be disposed on the insulating film 120 in the power line area V.

The power line PL is disposed on the third insulating film 123, as shown in FIG. 3, but this is shown as an example for better illustration. The power line PL may be disposed on any one of the first insulating film 121, the second insulating film 122 and the third insulating film 123 of the insulating film 120.

The power line PL may be disposed on the same layer as one electrode constituting the transistor TR in the display area AA. The power line PL may be disposed on the same layer as the first signal line W1 of the non-display area NA. The power line PL may be disposed on the same layer as one electrode constituting the driving circuit DC of the driving circuit area G.

The power line PL may be formed of the same material as the electrode constituting the transistor TR in the display area AA on any one insulating film 200 of the first insulating film 121, the second insulating film 122 and the third insulating film 123.

The power line PL may be formed of the same material as the electrode constituting the first signal line W1 of the non-display area NA. The power line PL may be formed of the same material as one electrode constituting the driving circuit DC of the driving circuit area G.

The power line PL may be disposed adjacent to the dam DM along the perimeter or a periphery of the dam DM or along the perimeter or periphery of the display area AA in the first to third non-display areas NA1 to NA3. The power line PL may be arranged to overlap at least one stopper 170.

The power line PL may be a low-potential power line for applying a low-potential voltage to the light-emitting diode 135 in the display area AA. For this purpose, the power line PL may be electrically connected to a second electrode E2 of the display area AA through a connection electrode CE disposed in the non-display area NA. The connection electrode CE may be disposed on a planarization film 140 and be connected to the second electrode E2 on the planarization film in the non-display area NA.

The planarization film 140 may be disposed on the transistor TR to protect the transistor TR and reduce steps formed by the transistor TR. In order to prevent generation of parasitic capacitance between the switching transistor SW, the gate line GL, the data line DL, and the organic light-emitting diode 135, the planarization film 140 may be disposed between the structures or devices thereof.

The planarization film 140 may include a single layer or multiple layers containing an organic material. The planarization film 140 may include a first organic film 141 and a second organic film 142 which are stacked. The second organic film 142 may be disposed on the first organic film 141.

The first organic film 141 may cover the transistor TR in the display area AA and extend to the non-display area NA. The first organic film 141 may be arranged to overlap the dam DM.

The first organic film 141 has a contact hole CH on the power line PL to connect the power line PL to the connection electrode CE in the power line area V, and the power line PL and the connection electrode CE are connected through the contact hole CH of the first organic film 141.

The first organic film 141 is disposed on the insulating layer 120 and extends from the display area AA to the non-display area NA.

The first organic film 141 covers the transistor TR in the display area AA to planarize the top surface thereof and covers the driving circuit DC and the first signal line W1 in the non-display area NA to planarize the top surface thereof. The first organic film 141 extends in the non-display area NA so as to overlap at least a part of the power line area V, and has a contact hole to expose the power line PL in the power line area V.

The first organic film 141 may cover a side or side portion of the power line PL and overlap the dam DM. The first organic film 141 is disposed to overlap at least one stopper 170 disposed between the dam DM and the driving circuit DC. The first organic film 141 may be arranged to overlap a plurality of stoppers 170.

A plurality of second signal lines W2 may be disposed on the first organic film 141. At least one of the second signal lines W2 may be electrically connected to the first signal line W1, and at least one of the remaining second signal lines W2 may not be electrically connected to the first signal line W1. The second signal line W2 may be arranged to overlap the driving circuit DC with the first organic film 141 interposed therebetween, thereby reducing the width of the non-display area NA and implementing a narrow bezel.

The first organic film 141 may include an organic material. The organic material includes at least one of an acrylic resin, a phenolic resin, a polyimide resin, an unsaturated polyester resin, a polyamide resin, benzocyclobutene, a polyphenylene resin, and a polyphenylene sulfide resin.

The first organic film 141 may be disposed as a composite stack including an inorganic insulating material film and an organic insulating material film.

The second organic film 142 may be disposed on the first organic film 141.

The second organic film 142 may extend from the display area AA to the non-display area NA. At least one of the first organic film 141 and the second organic film 142 may be disposed to overlap the dam DM.

The second organic film 142 covers the transistor TR and the first organic film 141 in the display area AA to planarize the top surfaces thereof, and covers the driving circuit DC and the second signal line W2 in the non-display area NA to planarize the top surface. The second organic film 142 extends to from the non-display area NA such that at least a part thereof overlaps the power line area V.

The second organic film 142 has an opening area exposing the contact hole CH of the first organic film 141 in the power line area V and exposes the stopper 170 on the first organic film 141 covering one side of the power line PL. The connection electrode CE may be connected to the power line PL through the opening area of the second organic film 142 and the contact hole CH of the first organic film 141.

The second organic film 142 may be disposed at the edge of the first organic film 141 to form a part of the dam DM. In this case, the second organic film 142 may not overlap the plurality of stoppers 170.

The second organic film 142 may include an organic material. The organic material includes at least one of an acrylic resin, a phenolic resin, a polyimide resin, an unsaturated polyester resin, a polyamide resin, benzocyclobutene, a polyphenylene resin, and a polyphenylene sulfide resin.

The second organic film 142 may be disposed as a composite stack including an inorganic insulating material film and an organic insulating material film.

In addition to the insulating film 120 described above, various organic or inorganic films may be further disposed between the substrate 111 and the planarization film 140.

The light-emitting diode 135 is disposed on the planarization film 140 in the display area AA. The light-emitting diode 135 may be electrically connected to the transistor TR through the planarization film 140. The light-emitting diode 135 includes a first electrode E1, a light-emitting layer EL, and a second electrode E2.

The first electrode E1 may function as an anode. The first electrode E1 may pass through the planarization film 140 and be connected to the transistor TR.

The first electrode E1 may include a metal material with high reflectivity. For example, the first electrode E1 has a multilayer structure such as a laminated structure (Ti/Al/Ti) of aluminum (Al) and titanium (Ti), a laminated structure (ITO/Al/ITO) of aluminum (Al) and ITO, an APC (Ag/Pd/Cu) alloy, a laminated structure (ITO/APC/ITO) of an APC alloy and ITO, or a laminated structure (Ag/MoTi) of silver (Ag) and molybdenum/titanium alloy, or a single layer structure containing any one selected from silver (Ag), aluminum (Al), molybdenum (Mo), gold (Au), magnesium (Mg), calcium (Ca), or barium (Ba), or an alloy containing two or more thereof. The first electrode E1 may be called a “reflective electrode”.

A light-emitting layer EL is provided on the first electrode E1. The light-emitting layer EL may include a hole injection layer, a hole transport layer, an organic light-emitting layer, an electron transport layer, and an electron injection layer.

When a voltage is applied to the first electrode E1 and the second electrode E2, holes are transferred to the organic light-emitting layer through the hole injection layer and the hole transport layer, electrons are transferred to the organic light-emitting layer through the electron injection layer and the electron transport layer, the holes recombine with the electrons in the organic light-emitting layer to form excitons, and the energy of excitons drops from the excited state to the ground state, thus causing light emission.

The light-emitting layer EL may include a red light-emitting layer that emits red light, a green light-emitting layer that emits green light, and a blue light-emitting layer that emits blue light. The red light-emitting layer, the green light-emitting layer, and the blue light-emitting layer may be arranged for each sub-pixel SP on the first electrode E1. The red light-emitting layer may be patterned in a red sub-pixel, the green light-emitting layer may be patterned in a green sub-pixel, and the blue light-emitting layer may be patterned in the blue sub-pixel, but these configurations are not limited thereto. At least two organic light-emitting layers among the red light-emitting layer, the green light-emitting layer, and a blue light-emitting layer may be stacked in one sub-pixel SP.

The light-emitting layer EL may be a white light-emitting layer that emits white light. In this case, the light-emitting layer EL may be a common layer in which one or more non-patterned layers are commonly disposed in the sub-pixels SP.

As previously described, the light-emitting layer EL may be arranged in a tandem structure of two or more stacks (STACK). In this case, each organic light-emitting diode 135 may include a charge generation layer disposed between stacks. The charge generation layer may be a common layer disposed on the entire surface of the display area AA.

A second electrode E2 is provided on the light-emitting layer EL. The second electrode E2 may function as a cathode.

For example, the second electrode E2 may be disposed not only in the light-emitting area of the sub-pixel SP but also in the entire region of the display area AA, but is not limited thereto. The second electrode E2 may be a common layer that is commonly disposed in the sub-pixels SP and applies the same voltage thereto. For this purpose, the second electrode E2 may be arranged to extend from the display area AA to a part of the non-display area NA. The second electrode E2 may extend to the driving circuit area G and be connected to the connection electrode CE in the driving circuit area G, for example, on the driving circuit DC.

The second electrode E2 may be a light-transmitting electrode. The second electrode E2 may include a transparent metal material (TCO, transparent conductive material) such as ITO (Indium Tin Oxide) or IZO (Indium Zinc Oxide) that can transmit light, or include a semi-transmissive conductive material such as magnesium (Mg), silver (Ag), or an alloy of magnesium (Mg) and silver (Ag). When the second electrode E2 is formed of a translucent metal material, light output efficiency can be increased due to microcavities.

As an example of the organic light-emitting diode 135, a front light-emitting type has been described above, but the organic light-emitting diode 135 of the present disclosure is not limited thereto. The organic light-emitting diode 135 may be a bottom-emitting type in which light emitted from the light-emitting layer EL is emitted toward the substrate 111. In this case, the first electrode E1 may be formed of a transparent or translucent electrode material, and the second electrode E2 may be formed of a reflective electrode material.

Meanwhile, the connection electrode CE is disposed on the planarization film 140 in the non-display area NA. The connection electrode CE is disposed for electrical connection between the second electrode E2 of the light-emitting diode 135 disposed in the display area AA and the power line PL.

The connection electrode CE may have a plurality of grooves, contact the second electrode E2 in the driving circuit area G, and be connected to the power line PL through the contact hole CH in the power line area V. The connection electrode CE may overlap the driving circuit DC and may contact the second electrode E2 on the driving circuit DC. The connection electrode CE may overlap at least one second signal line W2.

The connection electrode CE may be disposed on the same layer as the first electrode E1 of the light-emitting diode 135. The connection electrode CE may be formed of the same material as the first electrode E1 of the light-emitting diode 135.

A third organic film 143 may be disposed at the end of the first electrode E1 of the light-emitting diode 135. The third organic film 143 may be referred to as a “bank defining a light-emitting area”. The third organic film 143 is disposed to open the first electrode E1 of the light-emitting area and electrically insulate the first electrodes E1 between adjacent sub-pixels SP.

The third organic film 143 may extend from the display area AA to a part of the non-display area NA. The third organic film 143 exposes a part of the connection electrode CE in the driving circuit area G of the non-display area NA to connect the connection electrode CE and the second electrode E2 of the third organic film 143.

The third organic film 143 may extend to the non-display area NA to the power line area V such that at least a part of the third organic film 143 overlaps the power line area V, and may have an opening area that exposes sides of the planarization film 140 in the power line area V. The connection electrode CE may be connected to the power line PL through the opening of the third organic film 143 and the contact hole CH of the first organic film 141.

The third organic film 143 may be disposed at an edge of the substrate 111. In this case, the third organic film 143 is disposed to expose the stopper 170. The third organic film 143 may be disposed on the second organic film 141 in the non-display area NA to form a part of the dam DM.

The third organic film 143 may be formed of an organic material such as polyimide or hexamethyldisiloxane (HMDSO).

A fourth organic film 144 may be disposed on the third organic film 143. The fourth organic film 144 maintains a predetermined distance between a deposition mask disposed on the third organic film 143 and the third organic film 143 during formation of the light-emitting diode 135, and prevents the light-emitting diode 135 and the structures below from being damaged due to the deposition mask. The fourth organic film 144 may be called a “spacer”.

The fourth organic film 144 may be disposed in a pattern on the edge of the third organic film 143 having an opening for exposing the power line PL in the power line area V. The fourth organic film 144 may be disposed on the third organic film 143 constituting the dam DM so as to be formed as a part of the dam DM.

The fourth organic film 144 may be formed of any one of polyimide, photoacryl, and benzocyclobutene.

An encapsulation layer 150 is disposed on the organic light-emitting diode 135. The encapsulation layer 150 may cover the display area AA and the non-display area NA to prevent oxygen or moisture from permeating into the organic light-emitting diode 135. If necessary, other layers such as a capping layer may be interposed between the encapsulation layer 150 and the second electrode E2.

The encapsulation layer 150 may include multiple layers. The encapsulation layer 150 according to one embodiment of the present disclosure may include a first encapsulation layer 151, a second encapsulation layer 152, and an organic encapsulation layer 154 disposed between the first encapsulation layer 151 and the second encapsulation layer 152. The first and second encapsulation layers 151 and 152 may comprise or be inorganic encapsulation films.

The first encapsulation layer 151 may be disposed adjacent to the light-emitting diode 135, and the second encapsulation layer 152 may be disposed at the top of the encapsulation layer 150. In other words, the second encapsulation layer 152 may be a top layer of the encapsulation layer 150)

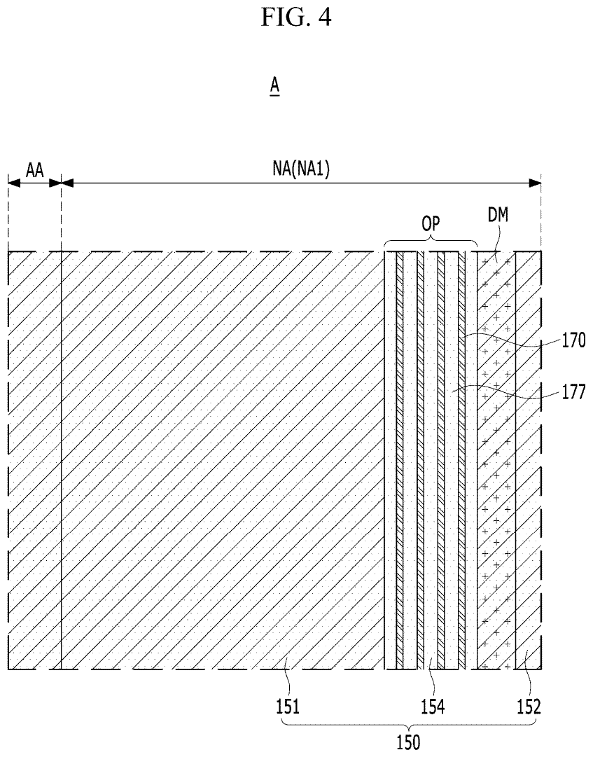

As shown in FIGS. 3 and 4, a stopper 170 may be disposed in the non-display area NA to control the flow of the encapsulation layer 150.

The stopper 170 may be disposed near the edge of the planarization film 140 at the non-display area NA and be adjacent to the dam DM. The stopper 170 may be disposed at an inner area than a region where the dam DM is positioned. The stopper 170 may be disposed closer to the display area AA than a region where the dam DM is positioned. The stopper 170 may be disposed at an inner area than the dam. The stopper 170 may be disposed between the contact hole CH and the dam DM of the planarization film 140. The stopper 170 may be disposed between the contact hole CH of the first organic film 141 and the dam DM. At least one stopper 170 may be arranged to overlap the power line area V. In this case, at least one stopper 170 may be arranged to overlap at least a part of the power line PL.

A plurality of stoppers 170 may be arranged to be spaced apart from each other and a trench 177 may be arranged between the plurality of stoppers 170. For example, the shape of the trench 177 may be disposed along a side (or side portion) of the stopper 170.

The film disposed in the space between the plurality of stoppers 170 may have a lower surface energy or surface tension than the surface energy or surface tension of the plurality of stoppers 170. In other words, the surface energy or surface tension of the plurality of stopper 170 may be higher than the surface energy or surface tension of the film disposed in the space between the plurality of stoppers 170.

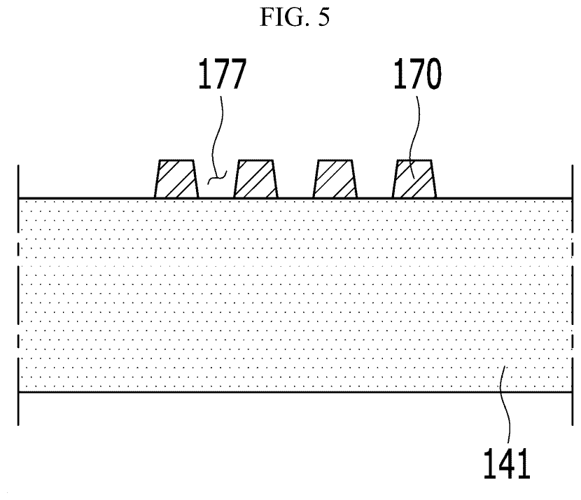

The top surface of at least one stopper 170 may include an inorganic material. An organic film may be disposed in the space (for example, the trench 177) spaced between the (for example, the trench 177) stoppers 170. For example, an organic film selected from the first organic film 141, the second organic film 142, and the third organic film 143 may be disposed in the space spaced between the plurality of stoppers 170. In one embodiment according to the present disclosure, as shown in FIG. 5, the first organic film 141 is exposed in the space spaced between the plurality of stoppers 170. The top surface of the first organic film 141 may be exposed in the trench 177.

The surface energy or surface tension of the stopper 170 having an inorganic material on the top thereof may be higher than the surface energy or surface tension of the first organic film 141 disposed in the trench 177 between the plurality of stoppers 170.

At least one stopper 170 protrudes from the top surface of the substrate 111 of the display panel 110 with respect to the top surface of the substrate 111 to form a protrusion pattern.

The protrusion pattern of the stopper 170 provides easy formation of the trench 177 between the plurality of stoppers 170. The height of the at least one stopper 170 from the top surface of the substrate 111 (in other words, the height of the at least one stopper 170 with respect to the top surface of the substrate 111) may be lower than the height of the dam DM from the top surface of the substrate 111 (in other words, the height of the dam DM with respect to the top surface of the substrate 111).

The stopper 170 may include an electrode material layer of an inorganic material, for example, a metal material.

Specifically, at least one stopper 170 may be disposed on the same layer as the connection electrode CE of the non-display area NA. At least one stopper 170 may be formed of the same material as the connection electrode CE of the non-display area NA. At least one stopper 170 may be disposed on the same layer as the first electrode E1 of the display area AA. At least one stopper 170 may be formed of the same material as the first electrode E1 of the display area AA.

As such, when the stopper 170 is disposed using the same process as the electrode material disposed in the display area AA, or when the stopper 170 is disposed using the same process as the electrode material disposed in the non-display area NA, the energy used to produce display devices can be reduced and the generation of greenhouse gases during the manufacturing process of the display device 100 can be reduced, thereby realizing desired ESG (Environmental/Social/Governance).

The stopper 170 may surround the display area AA. The stopper 170 may have a shape (or form) of a square frame surrounding the display area AA. At least one stopper 170 may be disposed along at least three sides of the display area AA. Specifically, the stopper 170 may be disposed in the first non-display area NA1, the second non-display area NA2, and the third non-display area NA3.

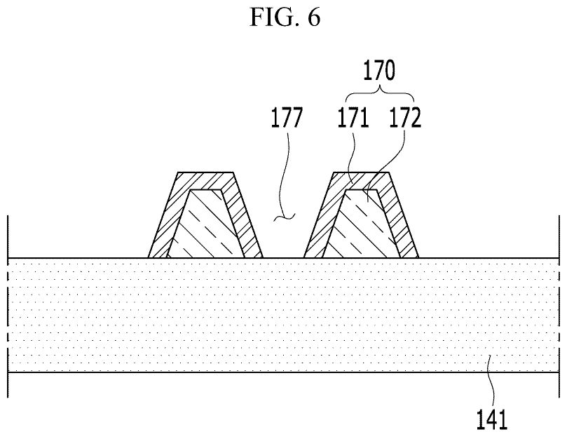

With reference to FIG. 6, a stopper 170 according to another embodiment of the present disclosure may include a first stop pattern layer 171 and a second stop pattern layer 172.

The second stop pattern layer 172 may be disposed on the first organic film 141 and the first stop pattern layer 171 may be disposed on the second stop pattern layer 172.

The surface energy or surface tension of the stopper 170 having an inorganic material on the top surface thereof may be higher than the surface energy or surface tension of the first organic film 141 disposed in the trench 177 between the a plurality of stoppers 170.

For this purpose, the second stop pattern layer 172 may be an organic film that may be disposed on the first organic film 141 during the manufacturing process of the display device 100. For example, a second organic film (see 142 in FIG. 3) disposed on the first organic film 141 may be used as the second stop pattern layer 172.

The first stop pattern layer 171 disposed at the uppermost part of the stopper 170 may include an electrode material layer, for example, a metal material, among inorganic materials.

Specifically, the first stop pattern layer 171 may be disposed on the same layer as the connection electrode CE of the non-display area NA. The first stop pattern layer 171 may be formed of the same material as the connection electrode CE of the non-display area NA. The first stop pattern layer 171 may be disposed on the same layer as the first electrode E1 of the display area AA. The first stop pattern layer 171 may be formed of the same material as the first electrode E1 of the display area AA. For example, the stopper 170 may contain ITO and Ag, and the top surface of stopper 170 may contain ITO.

The second stop pattern layer 172 protrudes from the top surface of the substrate 111 with respect to the top surface of the substrate 111 and the first stop pattern layer 171 on the second stop pattern layer 172 covers a side surface of the second stop pattern layer 172 and does not overlap at least a part of the first organic film 141 exposed by the trench 177.

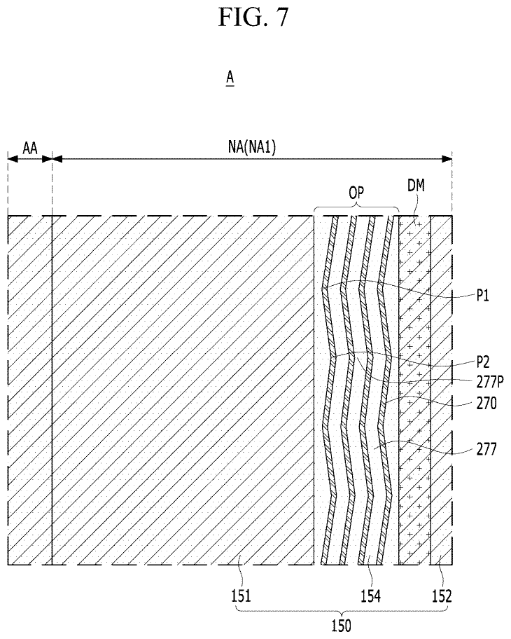

A stopper 270, or the like according to another embodiment of the present disclosure will be described with reference to FIG. 7. Configurations or components having the same reference numerals as that described with reference to FIGS. 1 to 6 may be applied or implemented in the same manner as the embodiments described with reference to FIGS. 1 to 6, or may be applied or implemented as embodiments combined with h the embodiments described with reference to FIGS. 1 to 6, and detailed descriptions of components having the same reference numerals may be omitted.

With reference to FIG. 7, the encapsulation layer 150 is disposed in the display area AA and the non-display area NA of the display panel 110, and a dam DM may be disposed around the encapsulation layer 150 or at the edge of the encapsulation layer 150 in the non-display area NA. At least one stopper 270 may be disposed inside the dam DM in the non-display area NA. In other words, at least one stopper 270 may be disposed adjacent to the inside of the dam DM in the non-display area NA. The inside of the dam DM refers to a part of the dam DM toward (or closer to) the display area AA. The dam DM may overlap the encapsulation layer 150 at the edge of the encapsulation layer 150.

A plurality of stoppers 270 may be arranged along the periphery of the display area AA.

A trench 277 may be disposed in the space between the plurality of stoppers 270. A plurality of trenches including the trench 277 may be arranged (in other words, there may be a plurality of trenches). Each of the plurality of stoppers 270 may have a first point P1 and a second point P2 orientated opposite to each other.

The first point P1 may protrude toward the display area AA, and the second point P2 may protrude toward the dam DM. A plurality of first points P1 may be arranged for one stopper 270, and a plurality of second points P2 may be arranged for one stopper 270. The first point P1 and the second point P2 may be alternately connected to each other and may be integrated with one stopper 270 (that is, may be an integral part of the one stopper 270). A segment of the stopper 270 connecting the first point P1 to the second point P2 may have a predetermined angle with respect to the dam DM.

The trench 277 at a position corresponding to the second point P2 may have a protruding pattern 277P that protrudes toward the dam DM. The protruding pattern 277P of the trench 277 may protrude toward the dam DM.

The film disposed in the space between the plurality of stoppers 270, for example, the trench 277, has a lower surface energy or surface tension than the surface energy or surface tension of the plurality of stoppers 270. In other words, the surface energy or surface tension of the stopper 270 may be higher than the surface energy or surface tension of the film disposed in the space between the plurality of stoppers 270.

An organic film, for example, an organic film selected from the first organic film 141, the second organic film 142, and the third organic film 143, may be disposed in the space between the plurality of stoppers 270. In one embodiment according to the present disclosure, the first organic film 141 is exposed to the space between the plurality of stoppers 270.

At least one stopper 270 may include an inorganic material in an upper part of the stopper 270. The least one stopper 270 may include an electrode material layer of an inorganic material, for example, a metal material.

Specifically, at least one stopper 270 may be disposed on the same layer as the connection electrode CE of the non-display area NA. At least one stopper 270 may be formed of the same material as the connection electrode CE of the non-display area NA. At least one stopper 270 may be disposed on the same layer as the first electrode E1 of the display area AA. At least one stopper 270 may be formed of the same material as the first electrode E1 of the display area AA. For example, the stopper 270 may contain ITO and Ag, and the top surface of the stopper 270 may contain ITO.

As such, when the stopper 270 is disposed using the same process as the electrode material disposed in the display area AA, or when the stopper 270 is disposed using the same process as the electrode material disposed in the non-display area NA, the production energy for producing a display device can be reduced and the generation of greenhouse gases during the manufacturing process of the display device can be reduced, thereby realizing desired ESG (Environmental/Social/Governance).

The stopper 270 may surround the display area AA. The stopper 270 may surround the display area AA and have a configuration in which the protruding first point P1 and the protruding second point P2 alternate with each other. At least one stopper 270 may be disposed along at least three sides of the display area AA, while having a plurality of protruding first points P1 and a plurality of protruding second points P2. Specifically, the stopper 270 may be disposed in the first non-display area NA1, the second non-display area NA2, and the third non-display area NA3.

An encapsulation layer 150 is disposed on the stoppers 170 according to one embodiment of FIG. 4 and the stopper 270 according to another embodiment of FIG. 7. The first encapsulation layer 151 constituting the encapsulation layer 150 is disposed in the display area AA and non-display area NA of the substrate 111.

As shown in FIG. 3, the first encapsulation layer 151 may be disposed on the entire top surfaces of the thin film transistor TR and the light-emitting diode 135 in the display area AA. The first encapsulation layer 151 may completely cover the light-emitting diode 135 to seal the light-emitting diode 135.

The first encapsulation layer 151 may extend to a part of the non-display area NA. The first encapsulation layer 151 may have an opening OP in the non-display area NA and the opening OP of the first encapsulation layer 151 may be disposed in an area corresponding to at least one stopper 170.

Specifically, the first encapsulation layer 151 overlaps one side of the first organic film 141 having the contact hole CH on the power line PL and one side of the dam DM. The first encapsulation layer 151 does not overlap the stopper 170 and the first organic film 141 exposed between the stoppers 170 through the opening OP. The stopper 170 and the first organic film 141 exposed between the stoppers 170 through the trench 177 may be disposed to overlap the opening OP of the first encapsulation layer 151.

The width of the opening OP of the first encapsulation layer 151 may be greater than a total width of the stoppers 170. The width of at least one stopper 170 may be 2 μm or less.

The first encapsulation layer 151 may be formed of an inorganic insulating material. For example, the first encapsulation layer 151 may include an inorganic insulating material such as silicon oxide, silicon nitride, and/or silicon oxynitride.

The organic encapsulation layer 154 is disposed on the first encapsulation layer 151 and the organic encapsulation layer 154 functions to planarize the top surface of the first encapsulation layer 151 to minimize cracks that may occur due to step coverage (or presence) of structures under the organic encapsulation layer 154.

The organic encapsulation layer 154 may contact at least one stopper 170 through the opening OP of the first encapsulation layer 151. Since the upper part of the stopper 170 contains an inorganic material, the organic encapsulation layer 154 alternately contacts the top surface of the inorganic material of the stoppers 170, and the top surface of the first organic film 141 through the opening OP of the first encapsulation layer 151.

The organic encapsulation layer 154 may fill the contact hole CH on the power line PL through the opening OP of the first encapsulation layer 151 and the trench 177 between the stoppers 170.

The organic encapsulation layer 154 is formed of an organic material and is flowable as a liquid during the manufacturing process of a display device. In order to control the flow of the organic encapsulation layer 154, the stopper 170 and the trench 177 are disposed in the non-display area NA outside the display area AA.

Specifically, the stoppers 170 are arranged in a protrusion pattern, and the trenches 177 between the stoppers 170 are filled with the organic encapsulation layer 154 to control the flow of the organic encapsulation layer 154.

In particular, the stopper 170 according to the present disclosure includes an inorganic material on the top surface thereof and exposes the top surface of the first organic film 141 in the trench 177 between the stoppers 170. The organic encapsulation layer 154 may alternately contact the top surface of the stopper 170 formed of an inorganic material and the top surface of the first organic film 141 through the opening OP of the first encapsulation layer 154.

In this case, the flow of the organic encapsulation layer 154 is interrupted by the top surface of the stopper 170 formed of an inorganic material with high surface energy or surface tension, and the overflowed organic encapsulation layer 154 spreads well within the trench 177 and fills the trench 177 without voids in the trench 177 due to the low surface energy or surface tension of the first organic film 141 exposed to the trench 177 between the stoppers 170.

As described above, the display device 100 according to the present disclosure has a configuration in which the first encapsulation layer 151 has an opening OP and the organic encapsulation layer 154 fills the contact hole CH on the power line PL through the opening OP to primarily control the flow of the organic encapsulation layer 154. Also, the display device 100 according to the present disclosure has a configuration in which the stoppers 170 having an inorganic material and the first organic film 141 are alternately disposed on the top surfaces contacting the organic encapsulation layer 154 to increase the difference in surface energy or surface tension, and a plurality of stoppers 170 and a plurality of trenches 177 are disposed to generate a plurality of energy barriers caused by the difference in surface energy or surface tension to further control the flow of the organic encapsulation layer 154.

That is, the organic encapsulation layer 154 alternately contacts the surface of the stopper 170, which has a higher surface tension or surface energy, and an inner surface of the trench 177, which has a lower surface tension or surface energy, and non-continuously contacts components having the same surface tension or surface energy. Therefore, the stopper 170 and the trench 177 according to the present disclosure act as bumps to stop or block the spread of the organic encapsulation layer 154 and thus control the spread of the organic encapsulation layer 154.

A typical stopper for controlling the flow of the organic encapsulation layer 154 may have a great height and a great width due to the great height. In the display device 100 according to the present disclosure, the organic encapsulation layer 154 alternately contacts the stopper 170 having a greater surface tension or surface energy than the surface energy or surface tension of the first organic film 141 and the first organic film 141 in the trench 177 through the opening OP, so that the flow of the organic encapsulation layer 154 can be controlled using an energy barrier. Therefore, the height of the stopper 170 may be reduced and the overall width of the stoppers 170 may be reduced. The display device 100 of the present disclosure can reduce the width of the stopper disposition area and thus reduces the bezel, thereby providing a narrow bezel.

The flow of the organic encapsulation layer 154 is controlled by the stopper 170 and the trench 177 according to the present disclosure described above and the overflow thereof can be prevented due to the dam DM disposed outside the stopper 170.

The organic encapsulation layer 154 may include one or more materials selected from the group consisting of polyethylene terephthalate, polyethylene naphthalate, polycarbonate, polyimide, polyethylene sulfonate, polyoxymethylene, polyarylate, and hexamethyldisiloxane.

The stopper 270 according to another embodiment of the present disclosure shown in FIG. 7 is arranged in the form of a zigzag pattern such that the first point P1 and the second point P2 are alternately disposed, to increase the difference in surface tension of contacting materials the organic encapsulation layer 154 and control the flow of the organic encapsulation layer 154. The stopper 270 is shown as having a zigzag pattern in FIG. 7 according to an embodiment, but the stopper 270 may have a curved pattern (in particular, a smoothly curved pattern) different from the zigzag pattern in another embodiment. Besides, different from the embodiment of the present disclosure shown in FIG. 7, the stopper 170 according to the embodiment of the present disclosure shown in FIG. 4 has a straight line pattern, but is not limited thereto.

The trench 277 according to another embodiment of the present disclosure has a protruding pattern 277P toward the dam DM, which is the flow direction of the organic encapsulation layer 154, and a plurality of protruding patterns including the protruding pattern 277P are disposed between the stoppers 270. The protruding patterns 277P may be disposed against the direction in which the organic encapsulation layer 154 spreads.

As a result, the display device 100 according to another embodiment of the present disclosure increases the surface area contacting the organic encapsulation layer 154 through the stopper 270 and the trench 277 having a protruding pattern 277P to increase the surface energy difference, to increase the resistance of the surface energy barrier in the direction opposite to the direction in which the organic encapsulation layer 154 spreads and improve the durability of the display panel 110 against deformation.

The display device 100 according to another embodiment of the present disclosure can improve durability to minimize deformation of the display panel 110.

In addition, in the display device 100 according to another embodiment of the present disclosure, the flow length of the organic encapsulation layer 154 is increased by the protruding patterns 277P to increase the resistance between the stoppers 270 per unit area, to effectively confine the organic encapsulation layer 154 within the trench 277 and control the flow of the organic encapsulation layer 154 due to improved hindrance of the flow of the organic encapsulation layer 154 even upon overflow of the organic encapsulation layer 154.

As such, the display device 100 according to the present disclosure can sufficiently control the flow of the organic encapsulation layer 154, thereby reducing the overall width of the stopper 170 as shown in FIG. 4 and the stopper 270 as shown in FIG. 7, reducing the bezel width of the display device 100, and realizing a narrow bezel.

A second encapsulation layer (can also be referred to as “upper encapsulation layer”) 152 may be disposed on the organic encapsulation layer 154.

The second encapsulation layer 152 may be adhered to the first encapsulation layer 151 (can also be referred to as “lower encapsulation layer”) in the area where the dam DM is disposed and cover the organic encapsulation layer 154. The second encapsulation layer 152 may completely cover the organic encapsulation layer 154 disposed in the display area AA and the non-display area NA. The second encapsulation layer 152 is combined with the first encapsulation layer 151 in the area where the dam DM is disposed, thereby preventing the organic encapsulation layer 154 from being exposed to the outside.

The second encapsulation layer 152 may extend to an end of the substrate 111, but is not limited thereto. As such, the first encapsulation layer 151 and the second encapsulation layer 152 constituting the encapsulation layer 150 are combined with each other on a side of the dam DM, and the organic encapsulation layer 154 is confined within the dam DM to prevent moisture or oxygen from permeating from the outside, reduce the occurrence of cracks due to moisture permeation, and thereby reduce deformation of the display panel 110.

The second encapsulation layer 152 may be formed of an inorganic insulating material. For example, the second encapsulation layer 152 may include an inorganic insulating material such as silicon oxide, silicon nitride, and/or silicon oxynitride.

The display device 100 according to the present disclosure can effectively reduce the overflow of the organic encapsulation layer 154, thereby reducing the overall width of the stopper 170 as shown in FIG. 4 and the stopper 270 as shown in FIG. 7, the number of dams DM, and thus the bezel width of the display device 100.

The flow of the organic encapsulation layer 154 is controlled by filling the contact hole CH of the first organic film 141 on the first power line PL through the opening OP of the first encapsulation layer 151. In addition, the flow of the organic encapsulation layer 154 can be further controlled due to the structures of the stopper 170 as shown in FIG. 4 and the stopper 270 as shown in FIG. 7 as well as the trench 177 as shown in FIG. 4 and the trench 277 as shown in FIG. 7 on the first organic film 141, at least a part of which overlaps the power line area V through the opening OP of the first encapsulation layer 151. In addition, the dam DM is provided outside the stopper 170 to prevent the overflow of the organic encapsulation layer 154.

As shown in FIG. 3, the dam DM is disposed outside the stopper 170 and the trench 177 and includes a second organic film 142, a third organic film 143, and a fourth organic film 144.

The dam DM may be disposed on the first organic film 141, the third organic film 143 may be disposed on the second organic film 142 of the dam DM, and the fourth organic film 144 may be disposed on the third organic film 143. The fourth organic film 144 may function as a spacer. The fourth organic film 144 can prevent the mask used during the manufacturing process of the display device 100 from damaging the light-emitting diode 135, especially the second electrode E2.

The dam DM has a height greater than the height of the stopper 170 disposed on the inside of the dam DM, and the first encapsulation layer 151 and the second encapsulation layer 152 may be formed on an inner surface (that is, a side surface closer to the display area AA) of the dam DM. The first encapsulation layer 151 and the second encapsulation layer 152 may be combined to confine the organic encapsulation layer 154 disposed between the first encapsulation layer 151 and the second encapsulation layer 152 inside the dam DM. The combined structure of the first encapsulation layer 151 and the second encapsulation layer 152 or the second encapsulation layer 152 extends along an outer surface (that is, a side surface closer to the outside) of the dam DM onto the substrate 111 outside the dam DM.

The display device 100 according to the present disclosure can prevent the permeation of gas such as oxygen or moisture from the outside through the structure of the encapsulation layer 150 combined with the stopper 170 and the dam DM, prevent cracks from occurring due to moisture penetration, and improve reliability.

The display device 100 can improve the reliability, to reduce the relative occurrence of defects, thereby reducing the production energy for producing the display device 100, and reducing the consumption of harmful production substances or regulated substances, thus being advantageous for recycling and realizing an eco-friendly display device 100.

As apparent from the foregoing contents, the display device according to one embodiment is capable of preventing oxygen from outside, improving permeation of moisture or reliability, and avoiding deformation.

The display device according to one embodiment is capable of effectively controlling the flow of the organic encapsulation layer by increasing the surface barrier or increasing resistance based on the difference in surface tension or surface energy.

The display device according to one embodiment is capable of reducing the bezel width, improving aesthetics and realizing a narrow bezel by reducing the number of stoppers or the width of the area where the stoppers are disposed.

The display device according to one embodiment is capable of reducing the consumption of materials used throughout the process of manufacturing the display device, improving recycling and reducing emission of greenhouse gases.

It will be apparent to those skilled in the art that various modifications and variations can be made in the disclosure without departing from the spirit or scope of the disclosure. Thus, it is intended that the disclosure cover such modifications and variations thereof, provided they fall within the scope of the appended claims and their equivalents.

What is claimed is:

1. A display device comprising:
a substrate including a display area and a non-display area;
an encapsulation layer at the display area and the non-display area, the encapsulation layer comprising a first encapsulation layer, an organic encapsulation layer, and a second encapsulation layer;
a dam around the encapsulation layer at the non-display area; and
at least one stopper disposed at an inner area than the dam at the non-display area,
wherein the first encapsulation layer has an opening at an area corresponding to the at least one stopper.

2. The display device according to claim 1, wherein the at least one stopper comprises a plurality of stoppers spaced apart from each other, and
wherein a surface energy or a surface tension of the plurality of stoppers is higher than a surface energy or a surface tension of a film disposed at a space between the plurality of stoppers.

3. The display device according to claim 1, wherein the organic encapsulation layer contacts the at least one stopper through the opening of the first encapsulation layer.

4. The display device according to claim 1, wherein the at least one stopper comprises a plurality of stoppers including an inorganic material,
a first organic film is disposed between the plurality of stoppers, and
the organic encapsulation layer alternately contacts a top surface of the inorganic material of one of the plurality of stopper and a top surface of the first organic film through the opening of the first encapsulation layer.

5. The display device according to claim 4, wherein the first encapsulation layer comprises an inorganic film, and
the first encapsulation layer not overlap the plurality of stoppers and the first organic film exposed between the plurality of stoppers through the opening.

6. The display device according to claim 1, wherein the at least one stopper comprises a plurality of stoppers, and
wherein a width of the opening of the first encapsulation layer is greater than a total width of the plurality of stoppers.

7. The display device according to claim 1, further comprising a light-emitting element at the display area, the light-emitting element comprising a first electrode, an organic light-emitting layer, and a second electrode,
wherein the at least one stopper comprises the same material as the first electrode.

8. The display device according to claim 1, wherein a height of the at least one stopper from the top surface of the substrate is smaller than a height of the dam from the top surface of the substrate.

9. The display device according to claim 1, wherein the non-display area comprises a driving circuit area and a power line area, and
the at least one stopper is arranged to overlap the power line area.

10. The display device according to claim 1, wherein the at least one stopper protrudes from the top surface of the substrate.

11. The display device according to claim 1, wherein the non-display area comprises a driving circuit area and a power line area,
the display device further comprises a connection electrode disposed at the driving circuit area and the power line area, and connected to a power line of the power line area, and
the at least one stopper comprises the same material as the connection electrode.

12. The display device according to claim 1, further comprising:
a driving circuit and a power line at the non-display area;
a first organic film disposed at least on the driving circuit and the power line;
a second organic film disposed on the first organic film; and
a connection electrode overlapping the power line and connected to the power line through a contact hole of the first organic film,
wherein the at least one stopper is disposed on the first organic film adjacent to the contact hole of the first organic film.

13. The display device according to claim 12, wherein at least one of the first organic film and the second organic film is disposed to overlap the dam.

14. The display device according to claim 12, wherein the stopper comprises:
a first stop pattern layer; and
a second stop pattern layer disposed below the first stop pattern layer,
wherein the first stop pattern layer comprises the same material as the connection electrode and the second stop pattern layer comprises the same material as the second organic film.

15. The display device according to claim 13, wherein the second stop pattern layer protrudes from the top surface of the substrate,
the first stop pattern layer is disposed on the second stop pattern layer such that the first stop pattern layer covers a side surface of the second stop pattern layer and does not overlap at least a part of the first organic film exposed in a trench between a plurality of stoppers, and
the first organic film between the plurality of stoppers contacts the organic encapsulation layer.

16. The display device according to claim 1, wherein the non-display area comprises a driving circuit area where a driving circuit is disposed and a power line area where a power line is disposed,
wherein the display device further comprises:
a plurality of first signal lines adjacent to the driving circuit in the driving circuit area;
a first organic film disposed at least in the driving circuit area and the power line area;
a second organic film disposed on the plurality of first signal lines; and
a plurality of second signal lines disposed on the first organic film so as to overlap the driving circuit,
wherein at least one of the plurality of second signal lines is connected to at least one of the plurality of first signal lines, and
another second signal line of the plurality of second signal lines is spaced apart from the driving circuit on the driving circuit area and comprises the same material as the at least one stopper.

17. The display device according to claim 1, wherein the at least one stopper comprises a plurality of stoppers,
a trench is disposed between the plurality of stoppers, and
the organic encapsulation layer fills the inside of the trench.

18. The display device according to claim 1, wherein the at least one stopper comprises a plurality of stoppers,
a trench is disposed between the plurality of stoppers,
each of the plurality of stoppers has a first point and a second point disposed in directions opposite to each other,
the first point protrudes toward the display area, and
the second point protrudes toward the dam.

19. The display device according to claim 18, wherein a plurality of first points including the first point and a plurality of second points including the second point are disposed,
the first points and the second points are alternately connected to each other, and
the trench corresponding to the second points has a pattern protruding toward the dam.

20. The display device according to claim 18, wherein the stopper connecting the first point to the second point has a predetermined angle with respect to the dam.

21. The display device according to claim 1, wherein the at least one stopper is disposed along at least three sides of the display area.
